(19) United States
(12) Patent Application Publication
(10) Pub. No.: US 2011/0069602 A1
(43) Pub. Date: Mar. 24, 2011

(54) PRODUCTION METHOD FOR AN OPTICAL RECORDING MEDIUM, AND OPTICAL RECORDING MEDIUM

(75) Inventor: Takeshi Miki, Tokyo (JP)

(73) Assignee: SONY CORPORATION, Tokyo (JP)

(21) Appl. No.: 12/880,575

(22) Filed: Sep. 13, 2010

(30) Foreign Application Priority Data
Sep. 18, 2009 (JP) P2009-216325

(51) Int. Cl. G11B 7/26; C23C 14/34

(52) U.S. Cl. 369/283; 264/129; 204/192.26; G9B/7.194

(57) ABSTRACT

A production method for an optical recording medium including a substrate, an information recording layer, and a light transmission layer, includes: molding the substrate; forming on the substrate the information recording layer so as to have a multilayer structure including a layer that has been sputtered under a first deposition condition and a layer that has been sputtered under a second deposition condition with use of targets of the same composition; and forming the light transmission layer on the information recording layer.

### CROSS REFERENCES TO RELATED APPLICATIONS

The present application claims priority to Japanese Priority Patent Application JP 2009-216325 filed in the Japan Patent Office on Sep. 18, 2009, the entire content of which is hereby incorporated by reference.

### BACKGROUND

The present application relates to an optical recording medium such as an optical disc and a production method therefor, more particularly, to a production method and structure of a recording layer of the optical recording medium.

In recent years, along with prevalence of personal computers, a start and prevalence of terrestrial digital broadcasting, and an acceleration in prevalence of hi-vision televisions in standard homes, an increase in a recording density and capacity of an optical disc as one of optical information recording media is progressing. For example, optical disc recording medium that is capable of recording a larger amount of information, such as a CD (Compact Disc), a DVD (Digital Versatile Disc), and a Blu-ray disc (registered trademark) are being provided.

A Blu-ray disc as a large-capacity optical disc recording medium is an optical disc having a diameter of about 12 cm and a thickness of about 1.2 mm. As a layer structure thereof in the thickness direction, an information recording layer is formed on a concavo-convex configuration of a substrate having a thickness of about 1.1 mm. The information recording layer is formed by sequentially laminating, for example, a reflective film (metal thin film), a dielectric film, a recording film, and a dielectric film.

A light transmission layer (cover layer) having a thickness of about 0.1 mm is formed on the information recording layer.

Such a Blu-ray disc has a recording capacity of about 25 GB (Giga Byte).

As a recording material of the recording film, there is known a material disclosed in, for example, Japanese Patent Application Laid-open No. 2008-112556.

### SUMMARY

Along with prevalence of Blu-ray discs (BDs), an improvement of efficiency in a production process of Blu-ray discs and a reduction in costs are strongly demanded.

For example, in a current Blu-ray disc, the information recording layer has a multilayer structure including a recording layer, a reflective film, and a dielectric film as described above, thus requiring a large-scale sputtering apparatus. Specifically, if the information recording layer is formed of multilayer films, an expensive deposition apparatus equipped with several deposition chambers is required in addition to a time for depositing the multilayer films.

Considering production efficiency and costs, a simple information recording layer having a single-film structure or the like is favorable.

However, when the information recording layer is formed of a single-film structure, durability thereof may be insufficient.

In view of the circumstances as described above, there is a need for an optical recording medium that has favorable durability and a simple layer structure for an information recording layer.

According to an embodiment, there is provided a production method for an optical recording medium including a substrate, an information recording layer, and a light transmission layer, the production method including: molding the substrate; forming on the substrate the information recording layer so as to have a multilayer structure including a layer that has been sputtered under a first deposition condition and a layer that has been sputtered under a second deposition condition with use of targets of the same composition; and forming the light transmission layer on the information recording layer.

For example, the information recording layer includes at least PdO and PdO₂.

Moreover, at least a flow rate of O₂ gas and a gas pressure used in the sputtering are different between the first deposition condition and the second deposition condition.

According to another embodiment, there is provided an optical recording medium including: a substrate; an information recording layer that is formed on the substrate so as to have a multilayer structure including a layer that has been sputtered under a first deposition condition and a layer that has been sputtered under a second deposition condition with use of targets of the same composition; and a light transmission layer that is formed on the information recording layer.

For example, the information recording layer includes at least PdO and PdO₂.

Specifically, in the embodiment, the information recording layer is of a single-film structure formed of the same material, but by varying the deposition condition during the sputtering, a pseudo multilayer structure constituted of a plurality of films is structured.

For example, with an oxide of In, Sn, or Zn being a main component, a material containing Pd and oxygen and in which an oxygen amount is larger than that of a stoichiometric composition in a case where In, Sn, or Zn described above is completely oxidized to become In₂O₃, SnO₂, or ZnO will be considered.

In this case, with In, Sn, or Zn being completely oxidized, oxygen atoms are bonded with at least a part of Pd atoms to become PdO or PdO₂, for example. Depending on a laser irradiation for recording, unstable Pd oxides such as PdO and PdO₂ react so as to form recording marks having reflectance different from peripheral reflectance.

In a case of a recording film material _{obtained} by adding PdO and PdO₂ to complete oxidization products as described above, since desired reflectance and transmittance and favorable recording/reproduction characteristics can be obtained with a single layer, the material is suited for a single-film structure.

However, a decomposition of PdO₂ and the like is considered to cause a deterioration of durability.

In this regard, a flow rate of O₂ gas and a gas pressure are varied during sputtering to form a layer with a reduced amount of Pd oxidization, for example. As a result, durability can be enhanced at a boundary of the information recording layer.

Although the information recording layer is formed as a single layer using the same material in the sputtering in the production method for an optical recording medium according to the embodiment, layers are formed while varying the deposition condition to thus obtain a pseudo multilayer structure constituted of a plurality of films. As a result, it is possible to form a film portion with enhanced durability and thus enhance durability of the entire information recording layer.

Since the sputtering apparatus can be realized by merely changing the deposition condition in one chamber, an improvement in production efficiency and a reduction in costs can be realized.

In other words, an optical recording medium having favorable durability can be provided while realizing an improvement in production efficiency and a reduction in costs.

Additional features and advantages are described herein, and will be apparent from the following Detailed Description and the figures.

### BRIEF DESCRIPTION OF THE FIGURES

FIG. 1 are explanatory diagrams of a structure of an optical disc according to an embodiment;

FIG. 2 are explanatory diagrams of production processes for an optical disc according to the embodiment;

FIG. 3 are flowcharts showing a production procedure for an optical disc according to the embodiment; and

FIG. 4 are explanatory diagrams of a multilayer optical disc according to the embodiment.

### DETAILED DESCRIPTION

The present application with be described below with reference to the drawings according to an embodiment.

1. Optical disc structure

2. Production procedure

3. Experimental examples

4. Application to multilayer disc

### 1. Optical Disc Structure

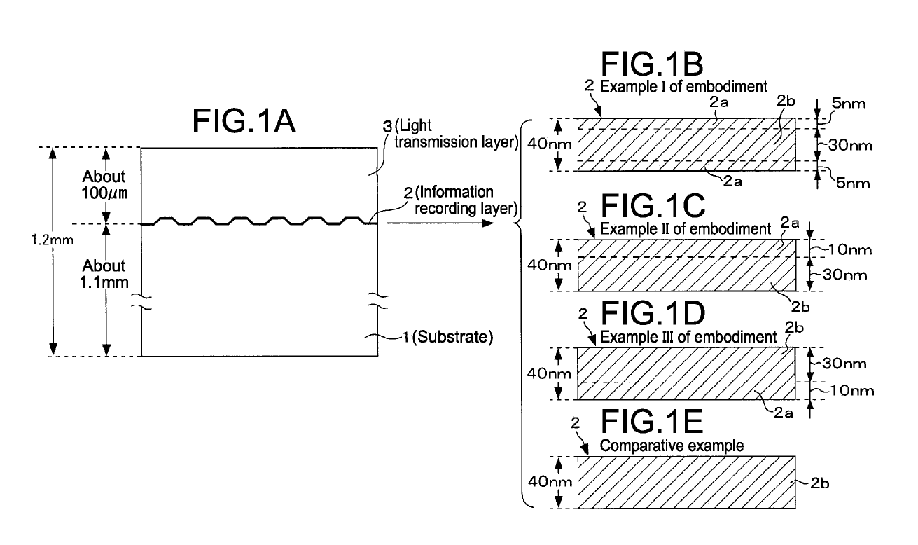

FIG. 1A schematically shows a layer structure of an optical disc according to an embodiment. FIG. 1A shows a structural example of a Blu-ray disc formed of a single-layer (information recording layer is provided as one layer).

In the optical disc of this embodiment, an information recording layer 2 and a light transmission layer (cover layer) 3 are formed on one side of a disc-like substrate 1 having a thickness of about 1.1 mm and an outer diameter of about 120 mm.

It should be noted that in the figure, an upper side is a laser incident surface that laser light enters during recording/reproduction.

The substrate 1 is formed by injection molding using, for example, a polycarbonate resin. At this time, through arranging a stamper onto which a concavo-convex configuration of wobbling grooves for tracking is transferred from a mastering matrix in a die, the substrate 1 is formed in a state where the concavo-convex configuration of the stamper is transferred to the substrate 1. In other words, the substrate 1 in which the wobbling grooves to be recording tracks are formed is formed by injection molding.

The information recording layer 2 is deposited on such a surface of the substrate 1, that is, a surface on which the concavo-convex configuration as the wobbling grooves is formed.

In the case of this embodiment, the information recording layer 2 contains an oxide of In (indium), Sn (tin), or Zn (zinc) as a main component. In addition, the information recording layer 2 includes Pd (palladium) and O (oxygen), and contains an oxygen amount which is larger than that of a stoichiometric composition in a case where In, Sn, or Zn is completely oxidized to become In₂O₃, SnO₂, or ZnO.

For example, the information recording layer 2 is formed as an In—Sn—Pd—O recording film, In—Pd—O recording film, an Sn—Pd—O recording film, or a Zn—Pd—O recording film.

The information recording layer 2 has, for example, the structure as shown in FIG. 1B (Example I of embodiment).

For example, the information recording layer 2 is formed as a single film of an In—Sn—Pd—O recording film or the like that has a thickness of 40 nm. It should be noted that as indicated by the broken lines, the information recording layer 2 has a pseudo 3-layer structure including first deposition condition layers 2a and a second deposition condition layer 2b.

In the case of FIG. 1B, the first deposition condition layer 2a having a thickness of 5 nm is formed on the substrate 1, the second deposition condition layer 2b having a thickness of 30 nm is formed on the first deposition condition layer 2a, and the first deposition condition layer 2a having a thickness of 5 nm is additionally formed on the second deposition condition layer 2b. The first deposition condition layers 2a and the second deposition condition layer 2b are each formed as an In—Sn—Pd—O recording film.

Moreover, the second deposition condition layer 2b having a thickness of 30 nm is a layer that mainly functions as a recording film, and the first deposition condition layers 2a sandwiching the second deposition condition layer 2b from above and below are layers that function to enhance durability of the information recording layer 2.

Further, as shown in FIG. 1C as Example II of the embodiment, the information recording layer 2 may have a pseudo 2-layer structure in which the second deposition condition layer 2b having a thickness of 30 nm is formed on the substrate 1 and the first deposition condition layer 2a having a thickness of 10 nm is formed on the second deposition condition layer 2b.

Furthermore, as shown in FIG. 1D as Example III of the embodiment, a pseudo 2-layer structure in which the first deposition condition layer 2a having a thickness of 10 nm is formed on the substrate 1 and the second deposition condition layer 2b having a thickness of 30 nm is formed on the first deposition condition layer 2a is also possible.

It should be noted that FIG. 1E shows a case of a simple single-film structure as a comparative example. In this case, an In—Sn—Pd—O recording film having a thickness of 40 nm is sputtered without changing the deposition condition, for example. As will be described later in experimental examples, durability may be deteriorated in this case.

The film thickness of 40 nm of the information recording layer 2 in FIG. 1 is a mere example. The thicknesses of the first deposition condition layers 2a and the second deposition condition layer 2b in the examples shown in FIGS. 1B to 1D are also mere examples.

As shown in FIG. 1A, an upper surface of the information recording layer 2 (laser irradiation surface side) functions as the light transmission layer 3.

The light transmission layer 3 is formed for protecting the optical disc. Recording/reproduction of information signals are performed by, for example, collecting laser light on the information recording layer 2 via the light transmission layer 3.

The light transmission layer 3 is formed by, for example, spin-coating an ultraviolet curable resin and curing it by irradiating ultraviolet rays. Alternatively, the light transmission layer 3 can be formed using an ultraviolet curable resin and a polycarbonate sheet, or an adhesive layer and a polycarbonate sheet.

The light transmission layer 3 has a thickness of about 100 μm so that, when combined with the substrate 1 having a thickness of about 1.1 mm, the thickness of the entire optical disc becomes about 1.2 mm.

It should be noted that though not shown, the surface of the light transmission layer 3 (laser irradiation surface) is sometimes hard-coated particularly for protecting a recording/reproduction quality of information signals from a mechanical impact to the optical disc and scratches and also preventing fingerprints of users from adhering onto the optical disc when handling it.

For the hard coat, an ultraviolet curable resin in which a silica gel fine powder is mixed for enhancing a mechanical strength, a solvent-type ultraviolet curable resin, a solventless-type ultraviolet curable resin, or the like may be used.

For providing a mechanical strength and removing an oil and fat content of a fingerprint and the like, the hard coat is performed in a thickness of 1 μm to several μm.

### 2. Production Procedure

Taking the structures shown in FIGS. 1A and 1B as an example, a production procedure of the optical disc of this embodiment will be described.

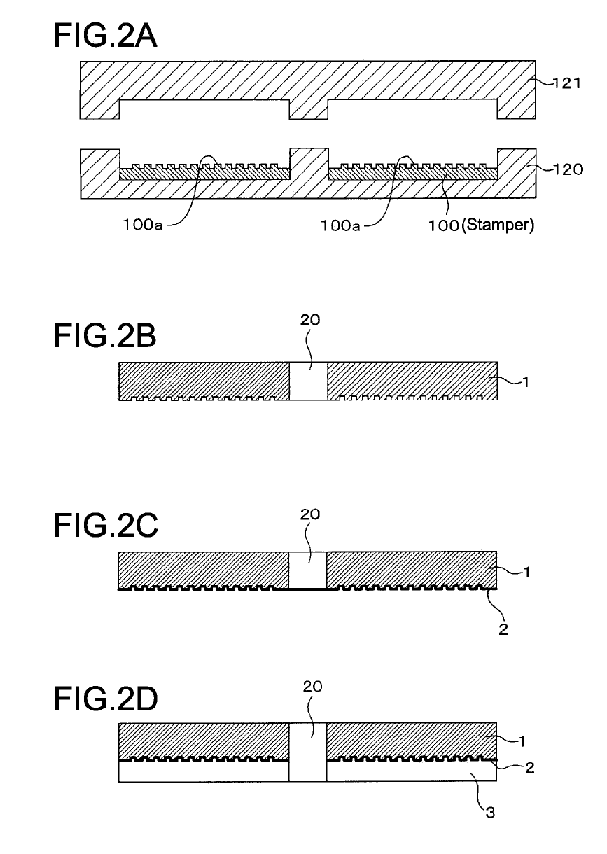

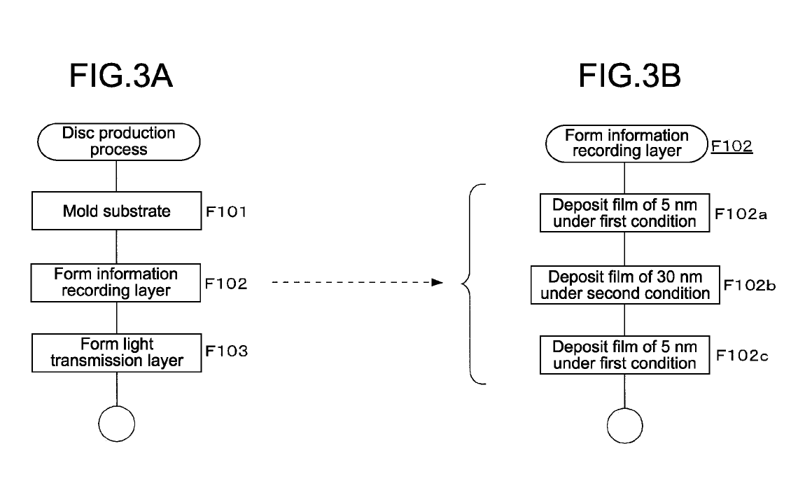

FIG. 2 are schematic diagrams each showing a state during an optical disc production process, and FIG. 3 are flowcharts showing the production process.

It should be noted that although the production process starts from a production of the substrate 1 using a stamper in this case, the stamper is formed by previous processes of matrix mastering, development, and a stamper production.

The substrate 1 is molded in Step F101 of FIG. 3A. A molded resin substrate 1 is molded by injection molding using, for example, a polycarbonate resin. On the substrate 1 molded herein, a concavo-convex pattern to be recording tracks (wobbling grooves) of the information recording layer 2 is formed.

FIG. 2A schematically shows a die for molding the substrate 1.

The die is constituted of a lower cavity 120 and an upper cavity 121, and the stamper 100 for transferring a concavo-convex pattern onto the information recording layer 2 are arranged in the lower cavity 120. A concavo-convex pattern 100a for transfer is formed on the stamper 100.

As a result of molding the substrate 1 by injection molding using such a die, the molded substrate 1 becomes a substrate as shown in FIG. 2B.

Specifically, the substrate 1 formed of a polycarbonate resin has a center hole 20 at a center thereof, and one surface side thereof is a concavo-convex pattern obtained by transferring the concavo-convex pattern 100a formed on the stamper in the die.

Subsequently, in Step F102 of FIG. 3A, the information recording layer 2 is formed. Specifically, the information recording layer 2 is deposited on the concavo-convex pattern of the substrate 1 by sputtering so as to have a thickness of, for example, 40 nm. FIG. 2C shows a state where the information recording layer 2 is deposited.

The formation of the information recording layer 2 is carried out as shown in FIG. 3B.

First, in Step F102a, a film having a thickness of 5 nm is deposited under a first deposition condition. In other words, the first deposition condition layer 2a shown in FIG. 1B is formed.

Subsequently, in Step F102b, a film having a thickness of 30 nm is deposited under a second deposition condition. In other words, the second deposition condition layer 2b shown in FIG. 1B is formed.

Then, in Step F102c, a film having a thickness of 5 nm is deposited under the first deposition condition again. In other words, the first deposition condition layer 2a on the light transmission layer 3 side shown in FIG. 1B is formed to complete the pseudo 3-layer structure as shown in FIG. 1B.

Here, a difference between the first and second deposition conditions is a gas pressure or a flow rate of O₂ gas during sputtering.

The gas pressure of the first deposition condition is lower than that of the second deposition condition.

The flow rate of O₂ gas of the first deposition condition is lower than that of the second deposition condition.

After the information recording layer 2 is formed as described above, the light transmission layer 3 is formed in Step F103 of FIG. 3A.

For example, an ultraviolet curable resin is flattened on the surface on which the information recording layer 2 is formed as shown in FIG. 2C by spin coat and cured by being irradiated with ultraviolet rays. As a result, the light transmission layer 3 is formed as shown in FIG. 2D.

After that, the surface of the light transmission layer 3 may be hard-coated. Moreover, print processing is carried out on the surface of the light transmission layer 3 on the substrate 1 side (label surface) to thus complete an optical disc such as a Blu-ray disc recordable (BD-R) after an inspection.

The information recording layer 2 formed as shown in FIG. 3B will be described.

The information recording layer 2 of the optical disc of this embodiment contains an oxide of In, Sn, or Zn as a main component. In addition, the information recording layer 2 includes Pd and oxygen, and an oxygen amount is larger than that of a stoichiometric composition in a case where In, Sn, or Zn is completely oxidized to become In₂O₃, SnO₂, or ZnO.

In other words, with In, Sn, or Zn being completely oxidized, oxygen atoms are bonded with at least a part of Pd atoms to become PdO or PdO₂.

This means that Pd and O are contained in addition to a stable oxide of In₂O₃, SnO₂, or ZnO, and PdO and PdO₂ react instead of In₂O₃, SnO₂, or ZnO when laser is irradiated.

Specifically, by the laser irradiation, PdO reacts to be decomposed into Pd and O₂, and PdO₂ reacts to be decomposed into PdO and O₂. Moreover, a bloat is structurally caused due to oxygen. Accordingly, recording marks having reflectance different from peripheral reflectance are formed.

By the information recording layer 2 as described above, extremely favorable recording/reproduction characteristics can be obtained. Sufficient characteristics as a Blu-ray disc can be obtained in terms of, for example, an SN of a reproduction signal, reflectance, transmittance, a recording sensitivity, and a recording margin.

Further, the structure is favorable for controlling reflectance and transmittance. Since a bonding state of Pd and oxygen in the recording films can be controlled based on the oxygen content and the like, the transmittance and reflectance of the recording layer can be controlled to desired values by controlling the bonding state of Pd and oxygen.

At this time, as the Pd atoms in the recording layer, there are three states including a state where a Pd atom exists independently and is not bonded with an oxygen atom (Pd), a state where a Pd atom is bonded with a single oxygen atom (PdO), and a state where a Pd atom is bonded with two oxygen atoms (PdO₂). Depending on the oxygen content, one to three states exist.

When a ratio of Pd atoms not bonded with oxygen atoms is high, metallic characteristics are enhanced, with the result that transmittance of the recording layer becomes small and reflectance of the recording layer becomes large. On the other hand, when a ratio of Pd atoms bonded with oxygen atoms is high, oxide characteristics are enhanced, with the result that transmittance of the recording layer becomes large and reflectance of the recording layer becomes small.

In other words, sufficient reflectance can be obtained with the information recording layer 2 of a single-film structure. For example, reflectance of about 17% can be obtained with ease.

Therefore, it is possible to structure the information recording layer 2 as a single-film structure instead of a structure including a reflective film. As a result, the layer structure can be made particularly simple.

Favorable recording/reproduction characteristics can be obtained by the single-film structure as that of the comparative example of FIG. 1E, for example.

In the case of a simple single-film structure as that shown in FIG. 1E, however, there has been a problem in durability, which is considered to be caused by decomposition of PdO₂ and the like.

In this regard, a flow rate of O₂ gas and a gas pressure are varied during sputtering, for example, to thus form a layer with reduced Pd oxidization. This layer is the first deposition condition layer 2a.

The flow rate of O₂ gas during sputtering influences Pd oxidization. If the flow rate of O₂ gas is small, Pd oxidization is reduced. In this regard, at the time of depositing the first deposition condition layers 2a (Steps F102a and F102c of FIG. 3B), the flow rate of O₂ gas and the gas pressure are made smaller than those at the time of depositing the second deposition condition layer 2b (Step F102b).

As a result, the first deposition condition layers 2a sandwiching the second deposition condition layer 2b from above and below as shown in FIG. 1B has reduced Pd oxidization and a lowered PdO₂ content ratio. Thus, durability can be enhanced at boundaries of the information recording layer 2. As a result, durability of the entire information recording layer 2 is enhanced.

It should be noted that the durability enhancement effect is also obtained when forming the first deposition condition layer 2a only on one side of the second deposition condition layer 2b as shown in FIGS. 1C and 1D.

Moreover, in addition to the flow rate of O₂ gas and the gas pressure, sputter power can be varied as the deposition condition to be varied. Since it becomes more difficult for oxidization to occur as sputter power is increased, sputter power at the time of depositing the first deposition condition layer 2a is made higher than that at the time of depositing the second deposition condition layer 2b.

By thus producing the optical recording medium, an optical recording medium having favorable durability can be provided while realizing an improvement of production efficiency and a reduction in costs.

Producing the optical recording medium in a single stamper chamber is of a grave importance in realizing a reduction in costs.

Specifically, since the information recording layer 2 has a single-film structure in terms of a material component and the pseudo 3-layer structure (or 2-layer structure) can be realized by merely changing the deposition condition in one chamber in a sputtering apparatus, an improvement of production efficiency and a reduction in costs can be realized.

In addition, with the first deposition condition layer 2a being a layer with suppressed Pd oxidization, durability of the information recording layer 2 can be enhanced.

It should be noted that although the examples of FIGS. 1B to 1D have taken the pseudo 2-layer structure or 3-layer structure constituted of the first deposition condition layer(s) 2a and the second deposition condition layer 2b as an example, it is also possible to provide a third deposition condition layer formed under still another deposition condition. In this case, the three layers shown in FIG. 1B are all sputtered under different deposition conditions, for example.

### 3. Experimental Examples

Hereinafter, experimental examples will be described.

In Experiment 1, the information recording layer 2 is formed as a simple single-film structure as in the comparative example shown in FIG. 1E. In Experiment 2, the information recording layer 2 is formed as a pseudo 3-layer structure while being a single-film structure as in FIG. 1B.

In the experimental examples, a Blu-ray disc recordable in which the information recording layer 2 has one single-layer disc structure as shown in FIG. 1A was produced, and test data was recorded and reproduced by a Blu-ray disc recording/reproducing apparatus.

Experiment 1

The disc structure includes a substrate 1 formed of polycarbonate, an information recording layer 2 as an In—Sn—Pd—O film having a thickness of 40 nm, and a cover layer 3 having a thickness of 100 μm.

The information recording layer 2 formed by sputtering is a single layer of an In—Sn—Pd—O film.

As the target, In₂O₃, SnO₂, and Pd were used.

A composition was adjusted by controlling sputter power of each target.

The compositions were set to be

In₂O₃:_{SnO2}=9:1

(_{In2O3}+SnO₂):Pd=6:4.

Ar gas and O₂ gas were used _{for} sputtering.

The gas flow rates were set to be Ar:70 sccm and O₂:30 sccm.

A disc evaluation was carried out by recording 5 consecutive tracks by 1-fold speed recording (4.92 m/sec) and measuring a jitter of a center track.

In this case, a value of the jitter was as favorable as 5.7%.

It should be noted that the jitter used herein is a generally-used index for a signal evaluation.

In general, reproduction of an optical disc is of a type that irradiates semiconductor laser light onto the disc and detects return light thereof. Signal characteristics are evaluated through accurately reproducing a recorded digital signal. The Blu-ray disc is specified to rotate at a linear velocity of 4.92 m/sec during reproduction with 1 clock of 15.15 ns and established by a pit and space of 2T to 8T (30.30 ns to 121.20 ns) (T represents channel clock cycle).

The jitter is expressed by a deviation from a specified clock that is represented by σ/T using a standard deviation σ and 1T.

It can be said that a reproduction signal is more deteriorated as the jitter value increases.

In the Blu-ray disc, for example, the jitter only needs to be 7% or less, but is of course the lower the better.

In the actual production, the jitter is 6% or less or the like considering a margin.

The optical disc of Experiment 1 in which the jitter is 5.7% as described above was favorable in this point.

Next, the optical disc of Experiment 1 was left under a high-temperature high-humidity environment (80° C., 85%) for 120 hours for checking durability thereof, and a jitter of the disc after the test was evaluated.

As a result, the jitter value largely increased to 18%. This value is absolutely unsuitable for practical use.

In other words, the optical disc of Experiment 1 was favorable at the beginning of the production in terms of recording/reproduction characteristics, but had a problem in durability.

Experiment 2

Next, an optical disc having a disc structure including a substrate 1 formed of polycarbonate, an information recording layer 2 as an In—Sn—Pd—O film having a thickness of 40 nm, and a cover layer 3 having a thickness of 100 μm was similarly produced.

It should be noted that by varying the gas flow rate during the deposition, the “In—Sn—Pd—O film (40 nm)” as the information recording layer 2 is structured to have 3 layers in terms of a deposition condition.

At the time of depositing the first 5 nm, Ar:30 sccm and O₂:2 sccm were set.

At the time of depositing the next 30 nm, Ar:70 sccm and O₂:30 sccm were ₛₑₜ.

At the time of depositing the final 5 nm, Ar:30 sccm and O₂:2 sccm were set.

Sputter power of the targets were all the same.

Here, the first and final layers each having a thickness of 5 nm are the first deposition condition layers 2a described above, and the layer having a thickness of 30 nm is the second deposition condition layer 2b.

Looking at the flow rate of O₂ gas in the deposition condition, while the flow rate was 30 sccm for the second deposition condition layer 2b, the flow rate was 2 sccm for the first deposition condition layers 2a. In other words, the oxygen amount was reduced when depositing the first deposition condition layers 2a.

Moreover, while the gas pressures were Ar:70 sccm and O₂:30 sccm for the second deposition condition layer 2b, the gas pressures were Ar:30 sccm and O₂:2 sccm for the first deposition condition layers 2a, thus lowering the entire gas pressure. This is for reducing an O₂ amount in a film in the first deposition condition layers 2a.

The conditions on both the flow rate of O₂ gas and the gas pressure are set so as to suppress a larger amount of Pd oxidization in the first deposition condition layers 2a than the second deposition condition layer 2b.

The disc evaluation was carried out by recording 5 consecutive tracks by 1-fold speed recording (4.92 m/sec) and measuring a jitter of a center track as in Experiment 1.

The jitter value was as favorable as 5.2%.

Next, the optical disc of Experiment 2 was left under a high-temperature high-humidity environment (80° C., 85%) for 120 hours for checking durability thereof, and a jitter of the disc after the test was evaluated.

As a result, a jitter value of 5.4% was obtained, which confirmed that the disc having this structure has extremely-high durability.

It was found from the experiment as described above that the currently-obtained information recording layer 2 produced by varying the deposition condition in the deposition within one chamber had extremely-favorable recording characteristics and extremely-favorable durability.

Since the information recording layer 2 can be produced in one chamber, a production of a BD-R disc and the like can be significantly simplified.

It should be noted that the values of the flow rate of O₂ gas and gas pressure used in Experiment 2 are mere examples, and the experiment does not necessarily need to be conducted under the conditions described above.

Moreover, it is also possible to vary one of the flow rate of O₂ gas and the entire gas pressure in view of suppressing Pd oxidization in the first deposition condition layers 2a.

Furthermore, sputter power may be varied as described above.

### 4. Application to Multilayer Disc

Heretofore, the embodiment has been described while taking a single-layer disc as an example. However, as the embodiment, a multilayer disc including two or more information recording layers 2 is also possible.

In particular, the information recording layer 2 contains an oxide of In, Sn, or Zn as a main component. In addition, the information recording layer 2 includes Pd and oxygen, and an oxygen amount is larger than that of a stoichiometric composition in a case where In, Sn, or Zn is completely oxidized. In this case, the reflectance and transmittance can be easily controlled based on the oxygen amount as described above. The fact that the reflectance and transmittance can be controlled based on the oxygen amount is extremely favorable in the case of a multilayer disc.

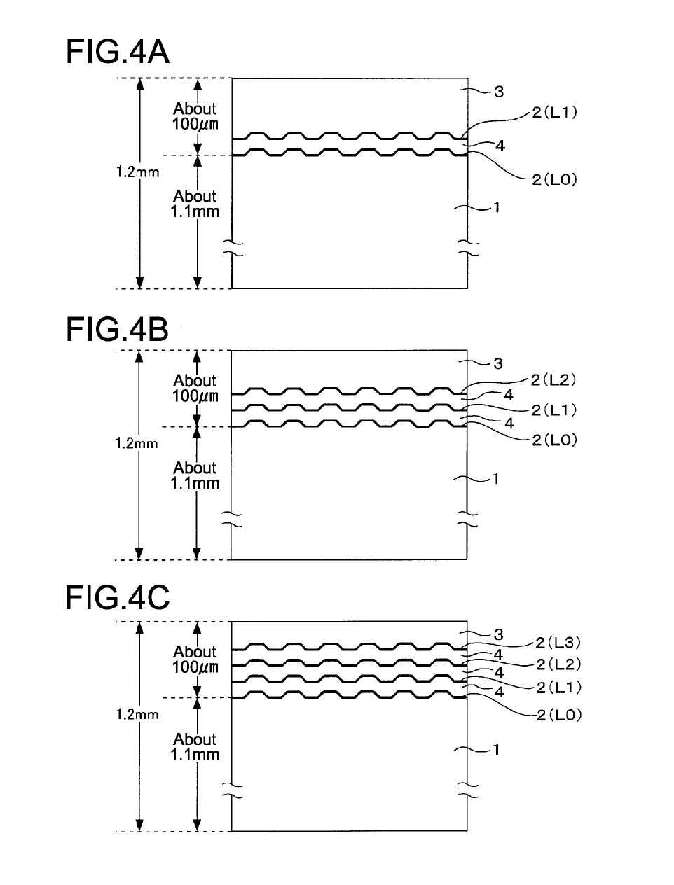

FIGS. 4A to 4C schematically show structures in the case of a multilayer disc.

FIG. 4A shows a case of a so-called dual layer disc that includes two layers of an L0 layer and an L1 layer each as the information recording layer 2.

The first information recording layer 2 (L0) is formed on the substrate 1, and the second information recording layer 2 (L1) is formed thereon via an intermediate layer 4. Then, the light transmission layer 3 is formed on the second information recording layer 2 (L1).

FIG. 4B shows a case of a 3-layer disc including 3 layers of an L0 layer, an L1 layer, and an L2 layer each as the information recording layer 2. Also in this case, the information recording layers 2 (L0), 2 (L1), and 2 (L2) are formed on the substrate 1 via the intermediate layers 4.

FIG. 4C shows a case of a 4-layer disc including 4 layers of an L0 layer, an L1 layer, an L2 layer, and an L3 layer each as the information recording layer 2. Also in this case, the information recording layers 2 (L0), 2 (L1), 2 (L2), and 2 (L3) are formed on the substrate 1 via the intermediate layers 4.

In FIGS. 4A to 4C, the intermediate layers 4 are each formed by, for example, spin-coating a light transmissive material having an ultraviolet photosensitivity by a spin coat method and curing the material by irradiating ultraviolet rays. When recording/reproducing information signals onto/from a multilayer optical disc recording medium, the arrangement and thickness of the intermediate layers 4 are set for suppressing interlayer crosstalk.

In the case of the multilayer discs, the layers on the laser irradiation surface side (L1 layer to L3 layer) need to be set with adequate reflectance and transmittance as compared to the L0 layer.

In other words, recording films of the L0 to L3 layers need to be set such that signal amounts from the layers when reading information become equivalent.

Also for the L0 to L3 layers each as the information recording layer 2, the layer is deposited as, for example, an In—Sn—Pd—O film. At this time, the layer is structured to have a pseudo 3-layer structure by varying the deposition condition during sputtering as described with reference to FIGS. 1B to 1D.

Regarding the second deposition condition layer 2b as a main layer for forming recording marks, desired reflectance and transmittance corresponding to each of the L0 to L3 layers can be obtained by controlling an oxygen amount at the time of sputtering.

Moreover, regarding the first deposition condition layers 2a each as the information recording layer 2, Pd oxidization is suppressed by varying the values of the flow rate of O₂ gas and gas pressure as compared to those at the time of depositing the second deposition condition layer 2b. As a result, information recording layers 2 (L0 to L3 layers) each having favorable durability can be formed.

It should be noted that the descriptions above have been given while taking the optical disc as an example. However, the present application is not limited to the disc-like optical recording medium and is also applicable to, for example, a card-type optical recording medium.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A production method for an optical recording medium including a substrate, an information recording layer, and a light transmission layer, the production method comprising:
molding the substrate;
forming on the substrate the information recording layer so as to have a multilayer structure including a layer that has been sputtered under a first deposition condition and a layer that has been sputtered under a second deposition condition with use of targets of the same composition; and
forming the light transmission layer on the information recording layer.

2. The production method for an optical recording medium according to claim 1,
wherein the information recording layer includes at least PdO and PdO₂.

3. The production method for an optical recording medium according to claim 2,
wherein at least a flow rate of O₂ gas used in the sputtering is different between the first deposition condition and the second deposition condition.

4. The production method for an optical recording medium according to claim 3,
wherein a gas pressure used in the sputtering is different between the first deposition condition and the second deposition condition.

5. An optical recording medium, comprising:
a substrate;
an information recording layer that is formed on the substrate so as to have a multilayer structure including a layer that has been sputtered under a first deposition condition and a layer that has been sputtered under a second deposition condition with use of targets of the same composition; and
a light transmission layer that is formed on the information recording layer.

6. The optical recording medium according to claim 5,
wherein the information recording layer includes at least PdO and PdO₂.
